(19) United States
(12) Patent Application Publication
(10) Pub. No.: US 2024/0219630 A1
(43) Pub. Date: Jul. 4, 2024

(54) CHIP PACKAGE AND MANUFACTURING METHOD THEREOF

(71) Applicant: Shanghai Xizhi Technology Co., Ltd., Shanghai (CN)

(72) Inventors: Yichen SHEN, Shanghai (CN); Huaiyu MENG, Shanghai (CN); Bo PENG, Shanghai (CN); Jinghui ZOU, Shanghai (CN); Xiaoling MU, Shanghai (CN); Yelong XU, Shanghai (CN)

(73) Assignee: Shanghai Xizhi Technology Co., Ltd., Shanghai (CN)

(21) Appl. No.: 18/399,030

(22) Filed: Dec. 28, 2023

(30) Foreign Application Priority Data
Dec. 30, 2022 (CN) 202211727099.6

(51) Int. Cl. G02B 6/12; G02B 6/124; G02B 6/42; H01L 23/00; H01L 25/065

(52) U.S. Cl. CPC G02B 6/12004; G02B 6/124; G02B 6/4204; H01L 24/45; H01L 25/0652; G02B 2006/12061; G02B 2006/12147; H01L 2224/45005; H01L 2224/4502; H01L 2924/12042; H01L 2924/19103

(57) ABSTRACT

The present disclosure relates to semiconductors technologies and provides a chip package and a manufacturing method of the chip package. The chip package includes: an interposer; a plurality of semiconductor chips optically connected to the interposer, wherein the plurality of semiconductor chips includes at least four semiconductor chips; and an optical interconnect chip optically connected to the interpose. Each of the plurality of semiconductor chips is configured to be optically connected to the optical interconnect chip via the interposer, to realize optical signal communication between any two of the plurality of semiconductor chips.

### CROSS-REFERENCE TO RELATED APPLICATION

This application claims priority to Chinese Patent Application No. 202211727099.6, filed on Dec. 30, 2022, the disclosure of which is incorporated herein by reference in its entirety.

### TECHNICAL FIELD

The present disclosure relates to semiconductors technologies, and in particular, to chip packages and a manufacturing method thereof.

### BACKGROUND

Optical interconnects are a key direction for integrated photonics applications. For example, the optical interconnects can provide advanced short-distance interconnect solutions for chips.

### SUMMARY

The present disclosure provides chip packages and a manufacturing method thereof.

In some embodiments, a chip package is proposed. The chip package includes: an interposer; a plurality of semiconductor chips optically connected to the interposer, wherein the plurality of semiconductor chips includes at least four semiconductor chips; and an optical interconnect chip optically connected to the interpose. Each of the plurality of semiconductor chips is configured to be optically connected to the optical interconnect chip via the interposer, to realize optical signal communication between any two of the plurality of semiconductor chips.

In some embodiments, a chip package is proposed. The chip package includes: an interposer; a plurality of semiconductor chips optically connected to the interposer, wherein the plurality of semiconductor chips includes a first semiconductor chip and a second semiconductor chip; and an optical interconnect chip optically connected to the interpose. The first semiconductor chip and the second semiconductor chip is configured to be respectively optically connected to the optical interconnect chip via the interposer, to realize optical signal communication between the first semiconductor chip and the second semiconductor chip.

In some embodiments, a manufacturing method of a chip package is proposed. The method includes: providing an interposer; mounting a plurality of semiconductor chips on the interposer, to optically connect the plurality of semiconductor chips to the interposer; and mounting an optical interconnect chip on the interposer, to optically connect the optical interconnect chip to the interposer.

Various aspects, features, advantages, etc., of the embodiments of the present disclosure will be described in detail below with reference to the accompanying drawings. The above aspects, features, advantages, etc., of the present disclosure will become clearer from the following detailed description in conjunction with the accompanying drawings.

### BRIEF DESCRIPTION OF THE DRAWINGS

FIG. 1 is a cross-sectional view of a chip package according to some embodiments of the present disclosure.

FIG. 2 is a top view of the chip package according to some embodiments of the present disclosure.

FIG. 3 is a cross-sectional view of an optical interconnect chip according to some embodiments of the present disclosure.

FIG. 4 is a cross-sectional view of a semiconductor chip according to some embodiments of the present disclosure.

FIG. 5 is a schematic flowchart of a manufacturing method of a chip package according to some embodiments of the present disclosure.

### DETAILED DESCRIPTION

In order to facilitate understanding of various aspects, features, and advantages of technical solutions of various embodiments of the present disclosure, the present disclosure is described in detail below in conjunction with the accompanying drawings. It should be understood that the various embodiments described below are only for illustration and are not intended to limit the scope of the present disclosure.

Hereinafter, exemplary embodiments will be described in more detail with reference to the accompanying drawings. The present disclosure may, however, be embodied in various different forms and should not be construed as limited to the embodiments shown herein. Rather, these embodiments are provided as examples so that the present disclosure will be thorough and complete, and will fully convey the aspects and features of the present disclosure to those skilled in the art. Therefore, processes, elements, and techniques, which are not necessary for those skilled in the art to fully understand the aspects and features of the present disclosure, may not be described. Unless otherwise stated, similar reference numbers refer to similar elements throughout the drawings and written description, and therefore, descriptions thereof may not be repeated. Additionally, features or aspects within each exemplary embodiment should typically be considered as available for other similar features or aspects in other exemplary embodiments.

It will be understood that when an element or feature is referred to as being “on,” “connected to”, or “coupled to” another element or layer, it can be directly on, connected to, or coupled to the another element or feature, or one or more intervening elements or features may be present therebetween. In addition, it will further be understood that when an element or feature is referred to as being “between” two elements or features, it may be the only element or feature between the two elements or features, or one or more other intermediate elements or features may be present between the two elements. The terms “first,” “second,” and other such numerical terms referring to structures do not imply a sequence or an order thereof, unless the context clearly dictates otherwise.

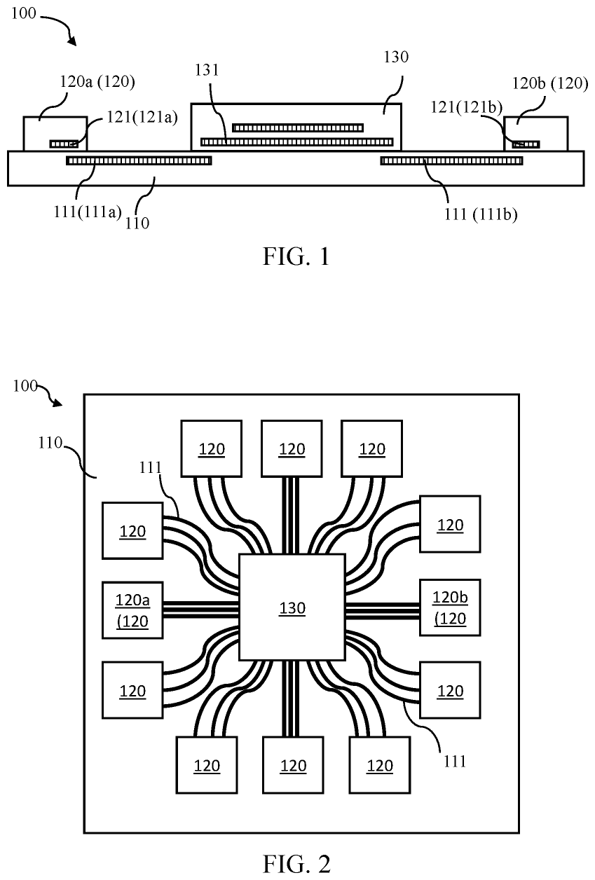

As shown in FIG. 1, in some embodiments, a chip package 100 is provided. The chip package 100 includes an interposer 110, a plurality of semiconductor chips 120, and an optical interconnect chip 130. The plurality of semiconductor chips 120 are optically connected to the interposer 110, and include a first semiconductor chip 120a and a second semiconductor chip 120b. The optical interconnect chip 130 is optically connected to the interposer 110. The first semiconductor chip 120a and the second semiconductor chip 120b is configured to be respectively optically connected to the optical interconnect chip 130 via the interposer 110, to realize optical signal communication between the first semiconductor chip 120a and the second semiconductor chip 120b.

The optical connection between the first semiconductor chip 120a and the second semiconductor chip 120b enables them to perform optical signal communication, avoiding delays, energy losses, etc., in electrical signal communication. Optical channels are provided in the optical interconnect chip 130 and the interposer 110 for the propagation the optical signals. The optical interconnect chip 130 may be designed to have a relatively complex waveguide arrangement, while the interposer 110 may have a relatively simple waveguide arrangement. An appropriate manufacturing method can be selected based on manufacturing costs and process requirements, and the optical interconnect chip 130 and the interposer 110 may be manufactured respectively. The interposer 110 may have a larger area than the optical interconnect chip 130 to carry the optical interconnect chip 130 and the semiconductor chips 120.

In this way, the interposer 110 and the optical interconnect chip 130 respectively play the role of optical connection, which can realize communication between the first semiconductor chip 120a and the second semiconductor chip 120b. In addition, the semiconductor chips 120 are optically connected to the interposer 110 to avoid electrical connection and electrical line transmission losses.

In FIG. 1, the interposer 110 is configured to carry the plurality of semiconductor chips 120 and the optical interconnect chip 130. The interposer 110 has a first surface and a second surface opposite to the first surface. In some embodiments, as shown in FIG. 1, the plurality of semiconductor chips 120 and the optical interconnect chip 130 are located on a same side, such as the first surface of the interposer 110. In some other embodiments, the optical interconnect chip 130 is located on the first surface of the interposer 110, and the plurality of semiconductor chips 120 are located on the second surface of the interposer 110.

In some embodiments, the semiconductor chips 120 and the optical interconnect chip 130 may be mounted on the interposer 110 through a bonding material. The bonding material may be an organic material, a metal material, a solder, etc.

Exemplarily, the interposer 110 includes a plurality of first waveguides 111, each of the semiconductor chips 120 includes a second waveguide 121 optically connected to the first waveguide 111, and the optical interconnect chip 130 includes a plurality of third waveguides 131 each optically connected to two of the first waveguides 111. In FIG. 1, each of the first semiconductor chip 120a and the second semiconductor chip 120b is connected to the optical interconnect chip 130 via the interposer 110. The optical interconnect chip 130 functions to interconnect and realizes optical connection between the first semiconductor chip 120a and the second semiconductor chips 120b.

For example, as shown in FIG. 1, the first semiconductor chip 120a is optically connected to a corresponding first waveguide 111 (111a) in the interposer 110 through the second waveguide 121 (121a) of the first semiconductor chip 120a. The first waveguide 111 (111a) is optically connected to the third waveguide 131 of the optical interconnect chip 130. The second semiconductor chip 120b is optically connected to a corresponding first waveguide 111 (111b) in the interposer 110 through the second waveguide 121 (121b) of the second semiconductor chip 120b. The first waveguide 111 (111b) is optically connected to the third waveguide 131 of the optical interconnect chip 130. Therefore, the first semiconductor chip 120a and the second semiconductor chip 120b have optical connection paths.

In some embodiments, the optical interconnect chip 130 is manufactured through a semiconductor process, while the interposer 110 may be manufactured based on a glass substrate or by other means, and they may be completed separately according to appropriate processes, thereby reducing costs.

In some embodiments, the semiconductor chips 120 are optically connected to the interposer 110 through at least one of evanescent coupling and grating coupler coupling. For example, the first waveguide(s) 111 in the interposer 110 is optically connected to the second waveguide(s) 121 in the semiconductor chip(s) 120 through the evanescent coupling. As another example, a waveguide end of the first waveguide 111 may be provided with a grating coupler, a waveguide end of the second waveguide 121 may be provided with a grating coupler, and the first waveguide 111 and the second waveguide 121 may be aligned through their respective grating couplers to achieve coupling.

In some embodiments, the optical interconnect chip 130 is optically connected to the interposer 110 through at least one of the evanescent coupling and the grating coupler coupling. For example, the third waveguide 131 in the optical interconnect chip 130 is optically connected to the first waveguide(s) 111 in the interposer 110 through the evanescent coupling or the grating coupler coupling.

FIG. 2 schematically shows a top view of the chip package 100 of FIG. 1. The semiconductor chips 120 are connected to the optical interconnect chip 130 through the first waveguides 111 in the interposer 110. Each semiconductor chip 120 may be connected to the optical interconnect chip 130 through a suitable number of first waveguides 111, and FIG. 2 only schematically illustrates some of the first waveguides 111. In some embodiments, any two semiconductor chips 120 in FIG. 2 are configured to implement optical communication. For example, any two semiconductor chips 120 are respectively connected to the optical interconnect chip 130 to realize optical connections through the corresponding third waveguide(s) (not shown in FIG. 2) in the optical interconnect chip 130. As shown in FIG. 1 and FIG. 2, the optical connection (optical communication) between any two semiconductor chips 120 may be achieved by configuring a sufficient number of third waveguides 131.

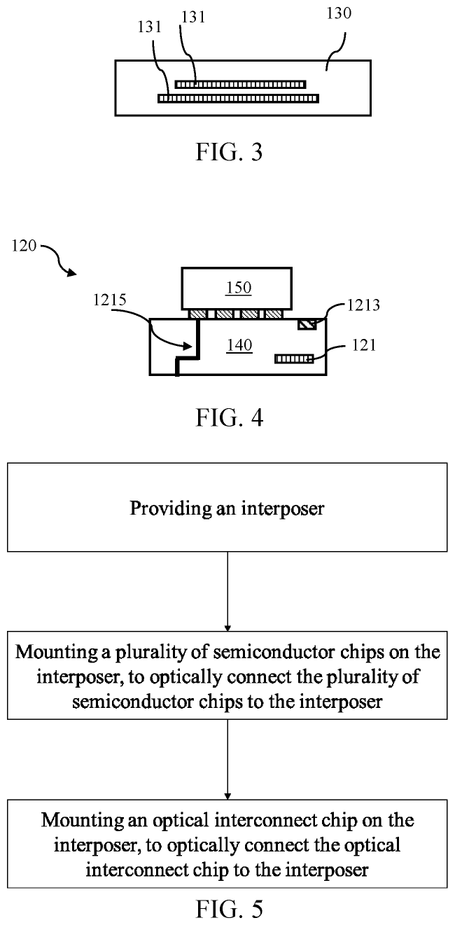

Referring to FIG. 3, in some embodiments, the plurality of third waveguides 131 in the optical interconnect chip 130 are arranged in at least two layers. For example, projections of the third waveguides in different layers on a surface of the optical interconnect chip 130 may intersect. The optical interconnect chip 130 has a smaller area than the interposer 110. Arranging the waveguides in layers in the optical interconnect chip 130 may allow more waveguides per unit area. In addition, the interposer 110 may have a larger area and may be suitable for arranging more semiconductor chips 120.

In some embodiments, the plurality of third waveguides in the optical interconnect chip 130 are arranged in at least two layers, and the at least two layers include a first layer and a second layer. The plurality of semiconductor chips 120 includes a first semiconductor chip, a second semiconductor chip, a third semiconductor chip, and a fourth semiconductor chip. The first semiconductor chip is optically connected to the interposer via one of the third waveguides in the first layer, so as to be optically connected to the second semiconductor chip through the interposer. The third semiconductor chip is optically connected to the interposer via one of the third waveguides in the second layer, so as to be optically connected to the fourth semiconductor chip through the interposer.

The interposer 110 includes a semiconductor substrate, a glass substrate, or an organic material substrate. The semiconductor chips 120 and the optical interconnect chip 130 may be fixed/mounted to the interposer 110 in a suitable manner, such as using bumps, soldering materials, organic adhesives, etc.

### Semiconductor Chips

The semiconductor chips 120 may include photonic devices, such as a light modulator, a light detector, a micro-ring resonator, a light beam splitter, etc. The semiconductor chip 120 may further include a photoelectric conversion unit, an electro-optical conversion unit, a photon computing unit, etc. The number of the various photonic devices or various units can be configured according to requirements, which may be one or more.

For example, the electro-optical conversion unit may include a modulator to convert an electrical signal into an optical signal. For example, the semiconductor chip 120 may be optically coupled with a laser or an optical fiber, thereby optical signals may be input to the semiconductor chip 120 or output from the semiconductor chip 120. For example, the waveguides may be used for propagation of optical signals and serve as information transmission channels. For example, the photoelectric conversion unit may include a photodetector for converting an optical signal into an electrical signal, and the photodetector may include, for example, a photodiode. For example, the semiconductor chip 120 includes a light source. The light generated by the light source may be coupled to the waveguides and may also be modulated by an electrical signal. The light source may be a laser or a light-emitting diode integrated into the semiconductor chip 120.

In some embodiments, the semiconductor chip 120 may include two chips or dies that are packaged. For example, referring to FIG. 4, the semiconductor chip 120 may be formed by bonding a first chip 140 and a second chip 150. The first chip 140 includes a conductive channel 1215. The conductive channel 1215 extends from a first surface of the first chip 140 to a second surface opposite to the first surface. The second chip 150 is disposed on the first surface of the first chip 140. The second surface of the first chip 140 faces the interposer 110 (for which, one can refer to FIG. 1). The first chip 140 may include at least one optical coupling structure 1213, and the optical coupling structure 1213 may be optically coupled with an optical fiber to input an optical signal to the first chip 140 or output an optical signal from the first chip 140.

### Optical Interconnect Chip

The optical interconnect chip 130 may include an optical coupling structure, a waveguide, a photoelectric conversion unit, an electro-optical conversion unit, a light source, and other photonic devices. The number of the various photonic devices may be configured as needed, which may be one or more. For example, the electro-optical conversion unit may include a modulator to convert an electrical signal into an optical signal. For example, the optical coupling structure may be used to be optically coupled with a laser or an optical fiber, so as to input an optical signal to the optical interconnect chip 130 or output an optical signal from the optical interconnect chip 130, for example, by using an optical fiber. The optical coupling structure may include a grating coupler, an end face coupler, etc. For example, the waveguide may be used for propagation of optical signals and serve as a channel for information transmission. For example, the photoelectric conversion unit may include a photodetector for converting an optical signal into an electrical signal, and the photodetector may include, for example, a photodiode. For example, the optical interconnect chip 130 includes a light source. The light generated by the light source may be coupled to the waveguides and may also be modulated by an electrical signal.

In some embodiments, the optical interconnect chip includes a plurality of third waveguides, and the plurality of third waveguides are arranged in at least two layers. Thus, although it has a smaller area (relative to the interposer 110), the optical interconnect chip 110 can still provide a sufficient number of waveguides.

### Interposer

The waveguides in the interposer 110 may be polymer waveguides, glass waveguides, silicon waveguides, silicon nitride waveguides, or the like. The interposer 110 may be manufactured based on different types of substrates, such as a semiconductor substrate, a glass substrate, a ceramic substrate. The semiconductor substrate may be silicon-on-insulator (SOI), stacked SiGe-on-insulator (S—SiGeOI), etc. In addition, other substrates may also be provided for manufacturing photonic integrated structures. The substrate material may be silicon, germanium, silicon carbide, gallium arsenide, or gallium phosphide, a compound semiconductor, an alloy semiconductor, etc., or a combination thereof. The substrate may be a wafer, such as an SOI wafer. Taking an SOI substrate as an example, the SOI substrate may include a back substrate, an insulating layer, and a top layer of silicon.

In some embodiments, the waveguides in the interposer 110 may be polymer waveguides, which may be formed by etching a polymer material layer.

In some embodiments, the waveguides in the interposer 110 may be glass waveguides, which may be formed based on a glass substrate. For example, a refractive index of local areas in the glass substrate may be changed by laser writing, to form the waveguides.

In some embodiments, the waveguides in the interposer 110 may be silicon waveguides or silicon nitride waveguides. For example, taking an SOI substrate to form the waveguides, the waveguides may include a back substrate, an insulating layer, and a top layer of silicon. The top layer of silicon may be etched to form the waveguides. For example, the waveguides may be formed by depositing a silicon nitride layer and etching the silicon nitride layer.

In some embodiments, the interposer 110 includes a conductive wiring layer, which may be used for transmission of electrical signals and may also be used to provide power for various types of chips. For example, the semiconductor chip 120 may be electrically connected to the interposer 110 according to functional requirements.

In some embodiments, a manufacturing method for a chip package is proposed, including: providing an interposer 110; mounting a plurality of semiconductor chips 120 on the interposer 110, to optically connect the plurality of semiconductor chips 120 to the interposer 110; and mounting an optical interconnect chip 130 on the interposer 110, to optically connect the optical interconnect chip 130 to the interposer 110. The chip package 100 in the embodiments of the present disclosure may be manufactured by the manufacturing method of the chip package.

According to various embodiments of the present disclosure, the optical connections of the semiconductor chips are realized through the interposer and the optical interconnect chip, a suitable packaging solution is provided for optical interconnects, which can be applied to complex optical interconnect scenarios between multiple semiconductor chips and has many advantages. For example, the interposer may have a larger area and be suitable for carrying more semiconductor chips, while the arrangement of optical interconnect chip may improve complexity and flexibility of the optical interconnects. In addition, the interposer and the optical interconnect chip may be manufactured and packaged independently.

Those skilled in the art should understand that what is disclosed above is only some implementation ways of the present disclosure and cannot be used to limit the scope of the patent protection claimed by the present disclosure. Equivalent changes made according to the implementation ways of the present disclosure still fall within the scope of claims of the present disclosure.

What is claimed is:

1. A chip package, comprising:
an interposer;
a plurality of semiconductor chips optically connected to the interposer, wherein the plurality of semiconductor chips comprises at least four said semiconductor chips; and
an optical interconnect chip optically connected to the interposer;
wherein each of the plurality of semiconductor chips is configured to be optically connected to the optical interconnect chip via the interposer, to realize optical signal communication between any two of the plurality of semiconductor chips.

2. The chip package of claim 1, wherein the interposer is configured to carry the plurality of semiconductor chips and the optical interconnect chip.

3. The chip package of claim 2, wherein the interposer comprises a plurality of first waveguides, each of the plurality of semiconductor chips comprises a second waveguide optically connected to a corresponding one of the first waveguides, and the optical interconnect chip comprises a plurality of third waveguides each optically connected to two of the first waveguides,
wherein the plurality of semiconductor chips comprises a first semiconductor chip and a second semiconductor chip,
the second waveguide of the first semiconductor chip is optically connected to the first waveguide corresponding to the first semiconductor chip,
the second waveguide of the second semiconductor chip is optically connected to the first waveguide corresponding to the second semiconductor chip, and
the first waveguide corresponding to the first semiconductor chip is optically connected to the first waveguide corresponding to the second semiconductor chip through one of the plurality third waveguides.

4. The chip package of claim 3, wherein the second waveguide is optically connected to the corresponding one of the first waveguides through at least one of evanescent coupling and grating coupler coupling, and
the third waveguides are optically connected to the first waveguides through at least one of evanescent coupling and grating coupler coupling.

5. The chip package of claim 2, wherein the plurality of semiconductor chips is optically connected to the interposer through at least one of evanescent coupling and grating coupler coupling.

6. The chip package of claim 2, wherein the optical interconnect chip is optically connected to the interposer through at least one of evanescent coupling and grating coupler coupling.

7. The chip package of claim 2, wherein the interposer comprises at least one of a semiconductor substrate, a glass substrate, or a ceramic substrate.

8. The chip package of claim 3, wherein the first waveguides of the interposer comprise at least one of polymer waveguides, glass waveguides, silicon waveguides, or silicon nitride waveguides.

9. The chip package of claim 3, wherein the plurality of third waveguides are arranged in at least two layers.

10. The chip package of claim 9, wherein:
the at least two layers comprise a first layer and a second layer;
the plurality of semiconductor chips further comprises a third semiconductor chip and a fourth semiconductor chip;
the second waveguide of the third semiconductor chip is optically connected to the first waveguide corresponding to the third semiconductor chip, the second waveguide of the fourth semiconductor chip is optically connected to the first waveguide corresponding to the fourth semiconductor chip,
the first waveguide corresponding to the third semiconductor chip is optically connected to the first waveguide corresponding to the fourth semiconductor chip through one of the plurality third waveguides,
the third waveguide optically connected to the first waveguide corresponding to the first semiconductor chip and the first waveguide corresponding to the second semiconductor chip is in the first layer, and
the third waveguide optically connected to the first waveguide corresponding to the third semiconductor chip and the first waveguide corresponding to the fourth semiconductor chip is in the second layer.

11. A chip package, comprising:
an interposer;
a plurality of semiconductor chips optically connected to the interposer, wherein the plurality of semiconductor chips comprises a first semiconductor chip and a second semiconductor chip; and
an optical interconnect chip optically connected to the interposer;
wherein the first semiconductor chip and the second semiconductor chip is configured to be respectively optically connected to the optical interconnect chip via the interposer, to realize optical signal communication between the first semiconductor chip and the second semiconductor chip.

12. The chip package of claim 11, wherein the interposer is configured to carry the plurality of semiconductor chips and the optical interconnect chip.

13. The chip package of claim 12, wherein the interposer comprises a plurality of first waveguides, each of the plurality of semiconductor chips comprises a second waveguide optically connected to a corresponding one of the first waveguides, and the optical interconnect chip comprises a plurality of third waveguides each optically connected to two of the first waveguides,
wherein the plurality of semiconductor chips comprises a first semiconductor chip and a second semiconductor chip,
the second waveguide of the first semiconductor chip is optically connected to the first waveguide corresponding to the first semiconductor chip, the second waveguide of the second semiconductor chip is optically connected to the first waveguide corresponding to the second semiconductor chip, and
the first waveguide corresponding to the first semiconductor chip is optically connected to the first waveguide corresponding to the second semiconductor chip through one of the plurality third waveguides.

14. The chip package of claim 13, wherein the second waveguide is optically connected to the corresponding one of the first waveguides through at least one of evanescent coupling and grating coupler coupling, and
the third waveguides are optically connected to the first waveguides through at least one of evanescent coupling and grating coupler coupling.

15. The chip package of claim 12, wherein the plurality of semiconductor chips is optically connected to the interposer through at least one of evanescent coupling and grating coupler coupling.

16. The chip package of claim 12, wherein the optical interconnect chip is optically connected to the interposer through at least one of evanescent coupling and grating coupler coupling.

17. The chip package of claim 12, wherein the interposer comprises at least one of a semiconductor substrate, a glass substrate, or a ceramic substrate.

18. The chip package of claim 13, wherein the first waveguides of the interposer comprise at least one of polymer waveguides, glass waveguides, silicon waveguides, or silicon nitride waveguides.

19. The chip package of claim 13, wherein the plurality of said third waveguides are arranged in at least two layers,
the at least two layers comprise a first layer and a second layer,
the plurality of semiconductor chips further comprises a third semiconductor chip and a fourth semiconductor chip,
the second waveguide of the third semiconductor chip is optically connected to the first waveguide corresponding to the third semiconductor chip,
the second waveguide of the fourth semiconductor chip is optically connected to the first waveguide corresponding to the fourth semiconductor chip,
the first waveguide corresponding to the third semiconductor chip is optically connected to the first waveguide corresponding to the fourth semiconductor chip through one of the plurality third waveguides,
the third waveguide optically connected to the first waveguide corresponding to the first semiconductor chip and the first waveguide corresponding to the second semiconductor chip is in the first layer, and
the third waveguide optically connected to the first waveguide corresponding to the third semiconductor chip and the first waveguide corresponding to the fourth semiconductor chip is in the second layer.

20. A manufacturing method of a chip package, comprising:
providing an interposer;
mounting a plurality of semiconductor chips on the interposer, to optically connect the plurality of semiconductor chips to the interposer; and
mounting an optical interconnect chip on the interposer, to optically connect the optical interconnect chip to the interposer.
